(19) United States
(12) Patent Application Publication
(10) Pub. No.: US 2021/0355338 A1
(43) Pub. Date: Nov. 18, 2021

(54) QUANTUM DOT INK, METHOD OF MANUFACTURING DISPLAY PANEL, AND DISPLAY PANEL

(71) Applicant: Shenzhen China Star Optoelectronics Semiconductor Display Technology Co., Ltd., Shenzhen (CN)

(72) Inventor: Shuren ZHANG, Shenzhen (CN)

(73) Assignee: Shenzhen China Star Optoelectronics Semiconductor Display Technology Co., Ltd., Shenzhen (CN)

(21) Appl. No.: 16/627,826

(22) PCT Filed: Dec. 18, 2019
(86) PCT No.: PCT/CN2019/126121

§ 371 Date: Dec. 31, 2019

(30) Foreign Application Priority Data
Dec. 6, 2019 (CN) 201911240876.2

(51) Int. Cl. C09D 11/50; C09D 11/52; C09D 11/322; C09D 11/36; C09D 11/037; C09D 11/033; H01L 33/06; H01L 27/15

(52) U.S. Cl. CPC C09D 11/50; C09D 11/52; C09D 11/322; C09D 11/36; H01L 33/0066; C09D 11/033; H01L 33/06; H01L 27/15; C09D 11/037

(57) ABSTRACT

A quantum dot ink, a method of manufacturing a display panel, and the display panel are provided. The quantum dot ink includes an organic solvent and quantum dots dispersed in the organic solvent. The quantum dots include luminescent quantum dots and blocking quantum dots. Dispersion effect of the quantum dot ink during inkjet printing is inhibited by adding the blocking quantum dots into the quantum do ink. This can prevent a coffee ring effect, and enhance smoothness and uniformity of a quantum dot film surface, thereby allowing the display panel to exhibit excellent display quality.

### CROSS REFERENCE

The present application claims priority to Chinese Patent Application No. 201911240876.2, filed on Dec. 6, 2019, filed for the invention titled “Quantum dot ink, method of manufacturing display panel, and display panel”, which is hereby incorporated by reference in its entirety.

### BACKGROUND OF INVENTION

### Field of Invention

The present disclosure relates to the field of display technology, and more particularly, to a quantum dot ink, a method of manufacturing a display panel, and the display panel.

### Description of Prior Art

Quantum dot light emitting diode display device is a self-luminous display technology without requirement of backlight. Quantum dot light emitting diode displays have broad application prospects due to advantages such as low energy consumption, ultra-thinness, wide viewing angles, strong color expression, wide operating temperature range, easy implementation of flexible display device, narrower luminous peak, and higher color saturation.

Inkjet printing technology is a key technology in manufacturing of quantum dot light emitting diode display devices. A uniformity of quantum dot layers formed by inkjet printing technology may affect display quality of the display devices. Ink containing quantum dots drips into designated areas through a printing nozzle during a process of forming the quantum dot layers. Quantum dot ink will disperse towards its surroundings due to fluidity of liquid ink, and will constantly solidify during dispersing, thereby forming a ring-shaped uneven quantum dot film surface, which is called “coffee ring effect”. However, since the fluidity of the quantum dot ink cannot be inhibited fundamentally, this results in limited improvement.

Thus, in order to prepare quantum dot light emitting diode display devices with high quality, the “coffee ring effect” should be eliminated.

During manufacturing processes of quantum dot light emitting diode display devices, inkjet printing technology is used for forming a quantum dot layer, and ink containing quantum dots drips into designated areas through a printing nozzle. Due to fluidity of liquid ink, quantum dot ink will disperse towards its surroundings, and constantly solidify during dispersion, thereby forming a ring-shaped uneven quantum dot film surface. That is, causing the coffee ring effect, which affects display quality of the display devices.

### SUMMARY OF INVENTION

To solve the abovementioned technical problems, the solution provided by the present disclosure is shown as follows:

The present disclosure provides a quantum dot ink, comprising an organic solvent, and a quantum dot dispersed in the organic solvent. The quantum dot comprises a luminescent quantum dot and a blocking quantum dot.

In one embodiment of the quantum dot ink of the present disclosure, the luminescent quantum dot is a spherical quantum dot.

In one embodiment of the quantum dot ink of the present disclosure, the blocking quantum dot is an oval quantum dot or a cylindrical quantum dot.

In one embodiment of the quantum dot ink of the present disclosure, a mass fraction of the luminescent quantum dot in the quantum dot ink is between 0.1% and 10%.

In one embodiment of the quantum dot ink of the present disclosure, a mass of the blocking quantum dot accounts for 1% to 20% of a mass of the luminescent quantum dot.

In one embodiment of the quantum dot ink of the present disclosure, the organic solvent comprises one or more of aromatic hydrocarbon, ether, and alcohol.

In one embodiment of the quantum dot ink of the present disclosure, a material of the quantum dot comprises one or more of a type II-VI quantum dot material, a type III-V quantum dot material and a type IV-VI quantum dot material.

In one embodiment of the quantum dot ink of the present disclosure, the material of the quantum dot comprises one or more of cadmium selenide, indium phosphide, and lead sulfide.

In one embodiment of the quantum dot ink of the present disclosure, the quantum dot ink further comprises a surface tension modifier and a viscosity modifier.

The present disclosure further provides a method of manufacturing a display panel, comprising:

forming an array layer on a substrate;

forming a luminescent layer on the array layer, and the luminescent layer comprises a quantum dot layer, and the quantum dot layer is formed by the quantum dot ink provided by the present disclosure via inkjet printing; and

forming a cover on the luminescent layer.

In one embodiment of the method of manufacturing the display panel of the present disclosure, the substrate layer is a glass substrate or a polyimide substrate, and the array layer comprises a data line, a scanning line, a thin film transistor, and a control electrode, and the data line, the scanning line, the thin film transistor, and the control electrode are configured to transmit signal and control signal.

In one embodiment of the method of manufacturing the display panel of the present disclosure, the luminescent quantum dot is a spherical quantum dot.

In one embodiment of the method of manufacturing the display panel of the present disclosure, step of forming the luminescent layer on the array layer comprises:

forming an anode layer on the array layer;

forming a hole injection layer on the anode layer;

forming a hole transporting layer on the hole injection layer;

forming a quantum dot layer on the hole transporting layer;

forming an electron transporting layer on the quantum dot layer;

forming an electron injection layer on the electron transporting layer; and

forming a cathode on the electron injection layer.

In one embodiment of the method of manufacturing the display panel of the present disclosure, the anode layer is formed by a chemical vapor deposition method, and a material used for forming the anode layer is indium tin oxide.

In one embodiment of the method of manufacturing the display panel of the present disclosure, the cathode is formed by lithium, magnesium, or aluminum.

In one embodiment of the method of manufacturing the display panel of the present disclosure, step of forming a quantum dot layer comprises:

preparing a quantum dot ink provided by the present disclosure;

injecting the quantum dot ink into a specified area of the display panel by using an inkjet printing apparatus; and

drying the display panel to remove the organic solvent existed in the quantum dot ink, to obtain the quantum dot layer.

In one embodiment of the method of manufacturing the display panel of the present disclosure, the drying method may be room temperature drying or high temperature drying.

The present disclosure further provides a display panel, comprising an array substrate, a luminescent layer disposed on the array substrate, and a cover disposed on the luminescent layer.

The luminescent layer comprises a quantum dot layer, and the quantum dot layer is formed by the quantum dot ink provided by the present disclosure via inkjet printing.

In one embodiment of the display panel of the present disclosure, the luminescent quantum dot is a spherical quantum dot, and the blocking quantum dot is an oval quantum dot or a cylindrical quantum dot.

In one embodiment of the display panel of the present disclosure, a mass fraction of the luminescent quantum dot in the quantum dot ink is between 0.1% and 10%, and a mass of the blocking quantum dot accounts for 1% to 20% of a mass of the luminescent quantum dot.

The present disclosure provides a quantum dot ink, a method of manufacturing a display panel by using the quantum dot ink, and the display panel manufactured by using the quantum dot ink. Dispersion effect of the quantum dot ink during inkjet printing is inhibited by adding blocking quantum dots into the quantum do ink. This prevents a coffee ring effect and enhances smoothness and uniformity of quantum dot film surface, allowing the display panel to exhibit excellent display quality.

### BRIEF DESCRIPTION OF DRAWINGS

In order to more clearly illustrate the technical solutions in the embodiments of the present invention, the drawings used in the description of the embodiments will be briefly described below. It is obvious that the drawings in the following description are only some embodiments of the present invention. Other drawings can also be obtained from those skilled persons in the art based on these drawings without making any creative effort.

FIG. 1 is a schematic view of printing a quantum dot film surface by using an inkjet printing apparatus according to one embodiment of the present invention. Quantum dot ink used in the inkjet printing apparatus is the quantum dot ink provided by embodiments of the present disclosure.

FIG. 2 is a schematic view of the display panel according to one embodiment of the present invention.

FIG. 3 is a flowchart of a method of manufacturing the display panel according to one embodiment of the present invention.

FIG. 4 is a flowchart of a method of forming the luminescent layer according to one embodiment of the present invention.

### DETAILED DESCRIPTION OF PREFERRED EMBODIMENTS

The description of each of the following embodiments is provided with reference to the appending drawings to exemplify the specific embodiment that may be implemented. The terms, such as “upper”, “lower”, “front”, “back”, “left”, “right”, “inside”, “outside”, “lateral sides”, etc. are based on the orientational or positional relationship shown in the drawings, and the terms are merely for convenience of description of the present invention, and thus they are not to be construed as limiting. In the drawings, similar units of the structures are shown in the same symbols.

One embodiment provides a quantum dot ink, a method of manufacturing a display panel by using the quantum dot ink, and the display panel manufactured by using the quantum dot ink. Dispersion effect of the quantum dot ink during inkjet printing is inhibited by adding blocking quantum dots into the quantum do ink, thereby eliminating the coffee ring effect and enhancing the smoothness and uniformity of the quantum dot film surface. The method of manufacturing the display panel provided by the embodiments can manufacture display panels with high quality.

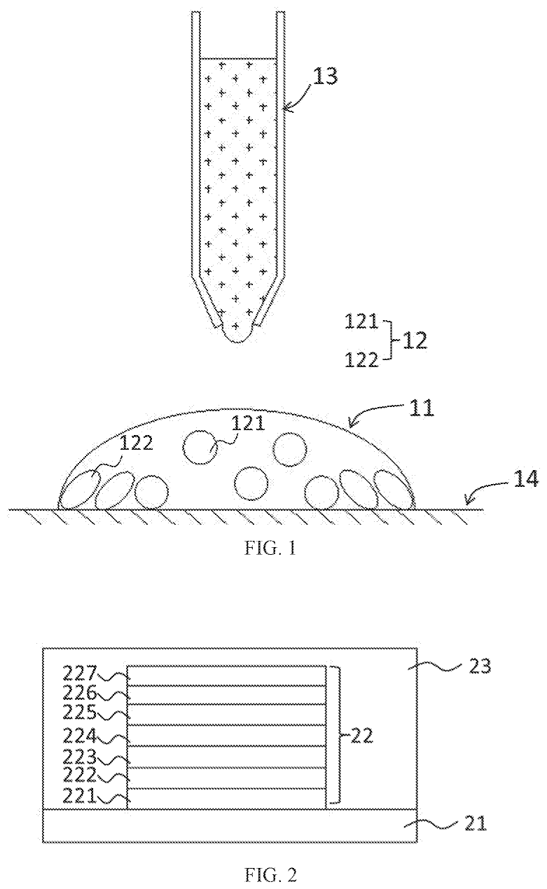

FIG. 1 is a schematic view of printing a quantum dot film surface by using an inkjet printing apparatus 13 according to one embodiment. Quantum dot ink used in the inkjet printing apparatus 13 is the quantum dot ink provided by the embodiments. Referring to FIG. 1, the quantum dot ink 11 provided by the embodiment comprises an organic solvent and quantum dots 12 dispersed in the organic solvent. The quantum dots 12 comprise luminescent quantum dots 121 and blocking quantum dots 122. It should be noted that the quantum dots 12 are luminescent crystals with a nanometer or micrometer size. The luminescent crystals have unique photoelectric characteristics, and may emit high quality light under stimulation of light or electricity. The luminescent quantum dots 121 can use their unique photoelectric characteristics to emit light, and are the luminescent crystals of the quantum dot ink 11. Although the blocking quantum dots 122 are also formed by quantum dot materials, energy bands of the blocking quantum dots 122 are wider than energy bands of the luminescent quantum dots 121. Thus, the energy used for emitting the luminescent quantum dots 121 cannot excite the blocking quantum dots 122 for lighting. That is, the blocking quantum dots 122 do not participate in lighting. The blocking quantum dots 122 have special shape and have poor fluidity in liquid, thereby preventing the quantum dot ink 11 from dispersing.

Referring to FIG. 1, during the process of printing a quantum dot film layer on a surface of a substrate 14 by using the inkjet printing apparatus 13, the quantum dot ink 11 may disperse towards its surroundings due to the fluidity of the liquid after dropping onto the substrate 14. The blocking quantum dots 122 located at an edge of ink droplets can prevent the droplets from dispersing, thereby limiting the quantum dot ink 11 to within a printing area, eliminating the coffee ring effect produced by dispersion of the ink droplets, and forming the quantum dot film with uniform surface. It should be understood that the substrate 14 can be any surface for forming the quantum dot film surface. For example, it can be the surface of the luminescent layer in the quantum dot light emitting diode.

Optionally, the luminescent quantum dots 121 are spherical quantum dots. It should be understood that the luminescent quantum dots 121 with spherical shape may produce uniform and high-quality light under light or electricity stimulation.

Optionally, the blocking quantum dots 122 are oval quantum dots or cylindrical quantum dots. It should be understood that the blocking quantum dots 122 with oval or cylindrical shape will cause an increase in their own potential energy during the long axis rolling process due to differences between the long axis and the short axis. Starting from the principle of minimum energy, the blocking quantum dots 122 have no tendency to disperse towards their surroundings. Other ingredients of the quantum dot ink 11 also cannot disperse due to the blocking effect provided by the blocking quantum dots 122, thereby eliminating the coffee ring effect during solidification of the quantum dot ink 11.

Optionally, the organic solvent in the quantum dot ink 11 may be one or more of aromatic hydrocarbon, ether, and alcohol. A material of the quantum dots 12 may be one or more of a type II-VI quantum dot material, a type III-V quantum dot material and a type IV-VI quantum dot material. For example, the material of the quantum dots 12 may be one or more of cadmium selenide, indium phosphide, and lead sulfide. The material of the luminescent quantum dots 121 and the material of the blocking quantum dots 122 may be the same, and may also be different.

Optionally, the quantum dot ink 11 further comprises a surface tension modifier and a viscosity modifier. The surface tension modifier is used to adjust the wetting of the quantum dot ink 11 on the surface of the substrate 14, allowing the quantum dot ink 11 to be spread on the surface of the substrate 14. The viscosity modifier is used to adjust the viscosity of the quantum dot ink 11, ensuring the continuity and stability of the ink droplets ejected by the inkjet printing apparatus 13.

Optionally, in the quantum dot ink, a mass fraction of the luminescent quantum dots 121 in the quantum dot ink is between 0.1% and 10%. A mass of the blocking quantum dots 122 accounts for 1% to 20% of a mass of the luminescent quantum dots. The above-mentioned composition ratio may fully exert the blocking effect of the blocking quantum dots 122 on the ink droplet dispersion under the premise of ensuring the optimal function of the finally formed quantum dot film layer.

Based on the above, the quantum dot ink provided by the embodiment comprises the luminescent quantum dots and the blocking quantum dots. During the inkjet printing process, the blocking quantum dots can prevent the dispersion effect of the quantum dot ink, thereby eliminating the coffee ring effect of the final quantum dot film surface, and enhancing the uniformity of the quantum dot film surface.

One embodiment further provides a method of manufacturing a display panel. Referring to FIG. 3, the method of manufacturing the display panel further comprises:

step S1: referring to FIG. 2, forming an array layer on a substrate to form an array substrate 21.

Optionally, the substrate may be a glass substrate or a polyimide substrate. The array layer may comprise a data line, a scanning line, a thin film transistor, and a control electrode, and the data line, the scanning line, the thin film transistor, and the control electrode are configured to transmit signal and control signal. The array substrate 21 may be formed by a chemical vapor deposition method and a dry/wet etching process. The array substrate 21 is used to provide data signal and control signal for the ultimately manufactured display panel.

Step S2. Referring to FIG. 2, forming a luminescent layer 22 on the array layer. The luminescent layer 22 comprises a quantum dot layer 224, and the quantum dot layer 224 is formed by quantum dot ink via inkjet printing.

Specifically, ink used for forming the quantum dot layer 224 via the inkjet printing method is the quantum dot ink provided by the embodiment mentioned above. Since the quantum dot ink comprises the luminescent quantum dots and the blocking quantum dots, the blocking quantum dots can prevent the quantum dot ink from dispersing, and enhance the smoothness and uniformity of the quantum dot film.

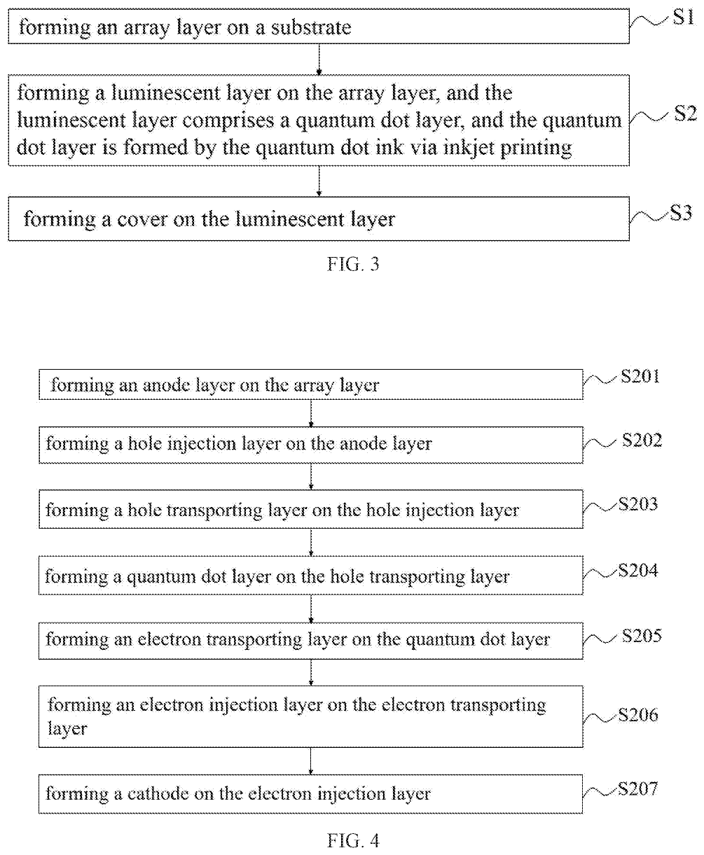

Furthermore, referring to FIG. 2 and FIG. 4, the step of forming the luminescent layer 22 on the array layer comprises:

Step S201: forming an anode layer 221 on the array layer.

Optionally, the anode layer 221 is formed via a chemical vapor deposition method. The anode layer 221 may be indium tin oxide electrode, and the anode layer 221 is used to manufacture hole particles required for the luminescent layer 22 to emit light.

Step 202: forming a hole injection layer 222 on the anode layer 221.

Optionally, a material of the hole injection layer 222 may be molybdenum oxide. It should be understood that the hole injection layer 222 is used to match the potential stack between the anode layer 221 and a hole transporting layer 223, ensuring the hole particles to be transmitted to the hole transporting layer 223.

Step S203: forming a hole transporting layer 223 on the hole injection layer 222.

The hole transporting layer 223 is formed by a material having high hole mobility rate, and the hole transporting layer 223 is used to transmit the hole particles to the quantum dot layer 224.

Step S204: forming a quantum dot layer 224 on the hole transporting layer 223.

Specifically, the step of forming the quantum dot layer 224 comprises:

Preparing the quantum dot ink according to the embodiment mentioned above. The quantum dot ink comprises the luminescent quantum dots and the blocking quantum dots. The quantum dot ink is used to emit light under stimulation of light or electricity. The blocking quantum dots are used to prevent the quantum dot ink droplets from dispersing, thereby preventing the coffee ring effect.

Injecting the quantum dot ink into a specified area of the hole transporting layer 223 by using an inkjet printing apparatus. It should be understood that the quantum dot ink enters the specified area of the hole transporting layer 223 in droplets during the process of inkjet printing. The quantum dot droplets remains in an aggregated state without dispersing after dropping onto the hole transporting layer 223 because the quantum dot ink contains the blocking quantum dots.

Drying the display panel to remove the organic solvent in the quantum dot ink to obtain the quantum dot layer 224. The drying method may be room temperature drying or high temperature drying. The liquid quantum dot ink will solidify after drying process to yield the quantum dot layer 224.

Step S205: forming an electron transporting layer 225 on the quantum dot layer 224.

The electron transporting layer 225 is formed by the electron-transporting material with high electron mobility. The electron transporting layer 225 is used to transport the quantum dot layer 224.

Step S206: forming an electron injection layer 226 on the electron transporting layer 225.

Optionally, a material of the electron injection layer 226 may comprise low work function materials such as lithium oxide and cesium oxide. The electron injection layer 226 is used to match the potential stack between a cathode 227 and the electron transporting layer 225, ensuring the electron particles are successfully transported to the electron transporting layer 225.

Step S207: forming a cathode 227 on the electron injection layer 226.

Optionally, the cathode 227 is formed by using low work function metals such as lithium, magnesium, and aluminum. The cathode 227 is used to produce the electron particles required for the luminescent layer 22 to emit light.

Step S3: forming a cover 23 on the luminescent layer 22.

Optionally, the cover 23 may be an encapsulation layer of the display panel, comprising an inorganic film layer and an organic film layer. The cover 23 may be a top glass cover of the display panel used for preventing internal devices from abrasion.

Optionally, the cover 23 covers the whole display surface of the display panel, thereby encapsulating, and protecting the display panel.

Based on the above, the embodiment provides the method of manufacturing the display panel. The quantum dot ink containing the blocking quantum dots is printed to form the quantum dot layer by using the inkjet printing technology. The quantum dot droplets are limited in a specific area without dispersing due to the inhibition effect of the blocking quantum dots on the droplets, thereby preventing the coffee ring effect. The quantum dot layer formed by the method has properties of smoothness and uniformity. The display panel manufactured by the method exhibits high display quality.

One embodiment further provides a display panel. Referring to FIG. 2, the display panel comprises an array substrate 21, a luminescent layer 22 disposed on the array substrate 22, and a cover 23 disposed on the luminescent layer 22.

The luminescent layer 22 comprises a quantum dot layer 224, and the quantum dot layer 224 is formed via the inkjet printing technology provided by the embodiment. Specifically, the quantum dot ink comprises luminescent quantum dots and blocking quantum dots. The luminescent quantum dots are used to emit light under stimulation of light or electricity. The blocking quantum dots are used to prevent the quantum dot ink droplet from dispersing during the process of inkjet printing and prevent the coffee ring effect. The quantum dot layer 224 has properties of smoothness and uniformity, and the display panel may exhibit excellent display quality.

Optionally, the luminescent layer 22 further comprises the array substrate 21 disposed on the anode layer 221, the hole injection layer 222 disposed on the anode layer 221, the hole transporting layer 223 disposed on the hole injection layer 222, the electron transporting layer 225 disposed on the quantum dot layer 224, the electron injection layer 226 disposed on the electron transporting layer 225, and the cathode 227 disposed on the electron injection layer 226. It should be understood that the hole particles emitted by the anode layer 221 and the electron particles emitted by the cathode 227 pass through transmissions by middle layers and converge on the quantum dot layer 224 to generate a photoelectric effect to induce the luminescent quantum dots in the quantum dot layer 224 to emit light.

Based on the above, the display panel provided by the embodiment comprises the quantum dot layer formed by the quantum dot ink provided by the embodiment. Under the actions of the blocking quantum dots on the quantum dot layer, the quantum dot layer has properties of smoothness and uniformity. The display panel exhibits high display quality.

It should be noted that the present disclosure has been described in the above preferred embodiments, but the preferred embodiments are not intended to limit the scope of the invention, and a person skilled in the art may make various modifications without departing from the spirit and scope of the application. The scope of the present application is determined by claims.

1. A quantum dot ink, comprising an organic solvent and quantum dots dispersed in the organic solvent, wherein the quantum dots comprise luminescent quantum dots and blocking quantum dots.

2. The quantum dot ink according to claim 1, wherein the luminescent quantum dots are spherical quantum dots.

3. The quantum dot ink according to claim 1, wherein the blocking quantum dots are oval quantum dots or cylindrical quantum dots.

4. The quantum dot ink according to claim 1, wherein a mass fraction of the luminescent quantum dots in the quantum dot ink is between 0.1% and 10%.

5. The quantum dot ink according to claim 4, wherein a mass of the blocking quantum dots accounts for 1% to 20% of a mass of the luminescent quantum dots.

6. The quantum dot ink according to claim 1, wherein the organic solvent comprises one or more of aromatic hydrocarbon, ether, and alcohol.

7. The quantum dot ink according to claim 1, wherein a material of the quantum dots comprises one or more of a type II-VI quantum dot material, a type III-V quantum dot material, and a type IV-VI quantum dot material.

8. The quantum dot ink according to claim 7, wherein the material of the quantum dots comprises one or more of cadmium selenide, indium phosphide, and lead sulfide.

9. The quantum dot ink according to claim 1, wherein the quantum dot ink further comprises a surface tension modifier and a viscosity modifier.

10. A method of manufacturing a display panel, comprising:
forming an array layer on a substrate;
forming a luminescent layer on the array layer, wherein the luminescent layer comprises a quantum dot layer, and wherein the quantum dot layer is formed by the quantum dot ink according to claim 1 via inkjet printing; and
forming a cover on the luminescent layer.

11. The method of manufacturing the display panel according to claim 10, wherein the substrate is a glass substrate or a polyimide substrate, and wherein the array layer comprises a data line, a scanning line, a thin film transistor, and a control electrode, and the data line, the scanning line, the thin film transistor, and the control electrode are configured to transmit signal and control signal.

12. The method of manufacturing the display panel according to claim 10, wherein the luminescent quantum dots are spherical quantum dots.

13. The method of manufacturing the display panel according to claim 10, wherein step of forming the luminescent layer on the array layer comprises:
forming an anode layer on the array layer;
forming a hole injection layer on the anode layer;
forming a hole transporting layer on the hole injection layer;
forming the quantum dot layer on the hole transporting layer;
forming an electron transporting layer on the quantum dot layer;
forming an electron injection layer on the electron transporting layer; and
forming a cathode on the electron injection layer.

14. The method of manufacturing the display panel according to claim 13, wherein the anode layer is formed by a chemical vapor deposition method, and a material used for forming the anode layer is indium tin oxide.

15. The method of manufacturing the display panel according to claim 13, wherein the cathode is formed by using lithium, magnesium, or aluminum.

16. The method of manufacturing the display panel according to claim 10, wherein the step of forming the quantum dot layer comprises:
preparing the quantum dot ink;
injecting the quantum dot ink into a specified area of the display panel by using an inkjet printing apparatus; and
drying the display panel to remove the organic solvent in the quantum dot ink to obtain the quantum dot layer.

17. The method of manufacturing the display panel according to claim 16, wherein a method of drying the display panel is room temperature drying or high temperature drying.

18. A display panel, comprising an array substrate, a luminescent layer disposed on the array substrate, and a cover disposed on the luminescent layer, wherein the luminescent layer comprises a quantum dot layer, and wherein the quantum dot layer is formed by the quantum dot ink according to claim 1 via inkjet printing.

19. The display panel according to claim 18, wherein the luminescent quantum dots are spherical quantum dots, and wherein the blocking quantum dots are oval quantum dots or cylindrical quantum dots.

20. The display panel according to claim 18, wherein a mass fraction of the luminescent quantum dots in the quantum dot ink is between 0.1% and 10%, and wherein a mass of the blocking quantum dots accounts for 1% to 20% of a mass of the luminescent quantum dot.
